(19) United States
(12) Patent Application Publication
(10) Pub. No.: US 2006/0087317 A1
(43) Pub. Date: Apr. 27, 2006

(54) Unified S-wave gravitational component detection instrument

(76) Inventor: David Arthur Harness, Monterey, CA (US)

Correspondence Address: David A. Harness, ASUC Building, 1st Floor, PMB #18, Berkeley, CA, 94720, US

(21) Appl. No.: 10/973,465

(22) Filed: Oct. 27, 2004

(51) Int. Cl. G01R 33/02

(52) U.S. Cl. 324/244

(57) ABSTRACT

An instrument which detects the gravitational field component of a standing or traveling transverse electromagnetic wave, as described by a symmetrically modified energy flux vector. The present modification of the general form of the Poynting energy flux vector S first notices the internal transverse expansion-restoring force of the electric and magnetic flux of the traveling wave and places that force on an even par with those same field's external interaction force, by means of adding an equal and opposite extremely weakly interacting gravitational cross product, from which the relativistic medium of the wave emerges, bringing a now symmetric unified gravitoelectromagnetic energy flux vector.

### REFERENCES CITED

Not applicable.

### FIELD OF THE INVENTION

The present invention relates to a means of detecting the gravitational field component of a unified standing or traveling transverse gravitoelectromagnetic wave, as described by a symmetrically modified Poynting energy flux vector S of the prior art.

### BACKGROUND OF THE INVENTION

The foremost challenge remaining to theoretical physics is to resolve the incompatibility between general relativity and quantum mechanics. The former has had extended success in describing physical phenomena on the large scale, while the latter has had extended success on the microscopic scale. It is widely held in the prior art that in resolving this incompatibility the laws governing gravity and quantum mechanics will be found to be limiting cases of a more fundamental theory.

The limits for general relativity begin wherein J. Wheeler (Princeton University) reports, the theory contains no means by which matter tells space how to curve and space tells matter how to move. Quantum mechanics has quite the same communication problem wherein B. Greene (The Fabric of the Cosmos, Random House, 2004) reports the theory lacks a means by which quarks and electrons interact with the Higgs ocean to effect inertia, and beyond that, interact the more strongly the greater their mass. Also critically lacking in the prior art is the means of communication by which the exchange of virtual particles carries the attractive forces, in their virtual or unobservable state; wherein all observed cases, when one mass emits a particle and that particle is absorbed by another mass, there is an effective repulsion from the would be line of attraction.

The extended success of quantum mechanics, however, has lead to the search for quantum gravity by means of the string/M-theory variations. B. Greene reports further that in first approximation each point of spacetime of Planck length 10⁻³³ cm resolution, is postulated to have 7 hidden “curled up” dimensions in addition to the 4 dimensions of space and time, which are similar to those of a sphere, which would allow for orthogonal vibrations along each of the sphere's added (r, φ, φ) dimensions. What is sought in the prior art is a unified set of multidimensional vibrations to a hidden string or membrane mechanical spacetime medium; where the first harmonic would carry the quantum gravitational force, and the higher harmonics of these multidimensional vibrations would carry the electric, magnetic, and nuclear forces vibrating faster and the more furiously the greater the mass of the particle-wave represented. In evaluating the success of prior embodiments however, the general consensus among the theoretical physics community remains that assigning realistic physical properties to even the first harmonic of the string/M-theory variations remains quite problematic.

### DESCRIPTION OF THE PREFERRED EMBODIMENT

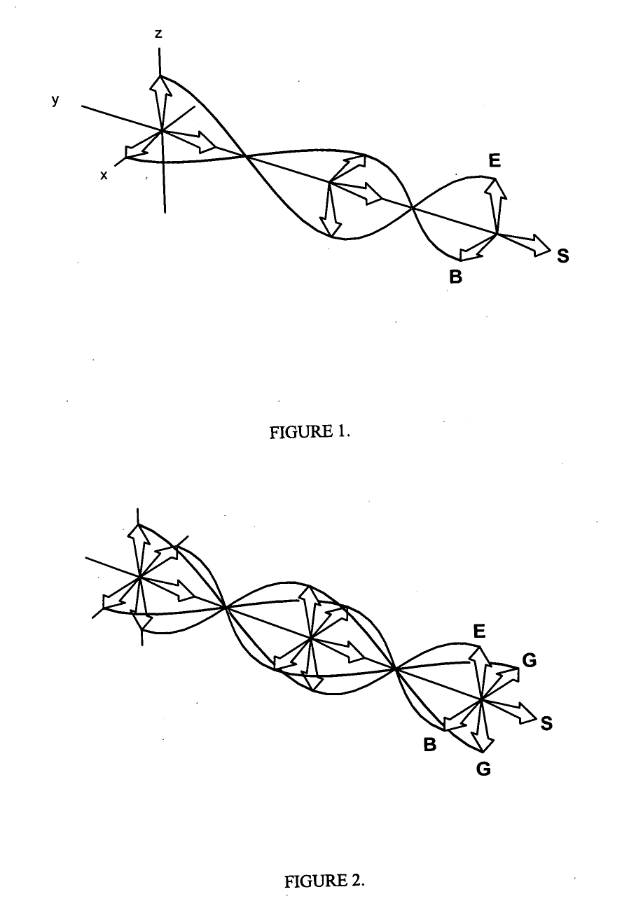

Revisiting first principles, the general form of the Poynting traveling energy flux vector S, as shown in FIG. 1, is

$$S = \frac{c}{4 π} ( E ⨯ B ) . \qquad ( 1 )$$

FIG. 1. The Poynting energy flux vector S, showing the electric E and magnetic B components expanding and contracting transversely to the wave's direction of travel.

The traveling flux can of course exert a force, but it is the transverse expansion of the flux itself along the E and B axes, as resultant of an expansion-restoring force, which is at issue in the present invention. Consequently, the prior art's lack of recognition of such an internal flux expansion-restoring force functioning on an even par with that same flux's external interaction force, is tantamount to embodying the position that nothing physical is occurring in the transverse field expansion of the energy flux vector.

F. Crawford (Waves, Berkeley Physics Course, Vol. III, McGraw-Hill, 1968) reports the basic linear oscillating form for a standing wave is
ψ(t)=A cos(ωt+φ). (2)
Further stating how in every case the physical meaning of ω²=return force per unit displacement per unit mass, and clarifying for universal application that, as in the case of electrical examples (LC circuit), the inertial mass may not actually be mass. The present invention thereby embodies an improvement over the prior art in now extending the significance of Newton's laws, in particular the third law wherein for every force in nature there is an equal and opposite force, to the most fundamental wave-particle form through the addition of a gravitational cross product proportional to the electric and magnetic cross product with G_{E}∝ −z E_{z} and G_{B}∝−x Bₓ, providing the mutual equal and opposite restoring force, thereby completing the cross of S as shown in FIG. 2, bringing a now symmetric unified energy flux vector, described by

$$S = \frac{c}{4 π} ( E ⨯ B + {G}_{E} ⨯ {G}_{B} ) . \qquad ( 3 )$$

FIG. 2. S-wave modification symmetry unifies with extremely weakly interacting gravitational flux components G, equally opposing their respective electric and magnetic counterparts, indicating the mutual relativistic medium.

The standing waveform of EQ. (2) is correct, as opposed to that of the analogy of a traveling wave on a string, since the entity that provides the restoring force for a wave deflection performs the function of the medium for the wave propagation, the concept being here ω²=return force per unit displacement per unit flux. Consequently there is no string, in that the electromagnetic and gravitational cross products expand transversely relative to each other; thereby the gravitational components are the medium for the electric and magnetic components, and the electromagnetic the medium for the gravitational. The electromagnetic and gravitational cross products of course both expand with the familiar condition of traveling at the speed of light relative to any inertial frame observer, making their relative medium the relativistic medium.

In the present embodiment there is then no need to reference beyond the relativistic medium to an unobservable mechanical medium. The present embodiment is then of course highly analogous to the orthogonal expansion and restoring force one might expect should be included in the prior art, but which is lacking in its traveling multidimensional hidden mechanical background string or membrane vibrations. In the present field expansion embodiment the gravitational components have of course remained hidden due to their even weaker coupling and lack of polarization. E. Wichman (Quantum Physics, Berkeley Physics Course, Vol. IV, McGraw-Hill, 1967) reports the fine structure constant

$$α = \frac{{e}^{2}}{ℏ c}$$

in cgs units is a dimensionless quantity which indicates the strength of electrostatic coupling between two electrons. The same concept is applied to the gravitational interaction, wherein the relative strength of their gravitational to electric ratio is found by putting

$$\frac{{m}_{electron}^{2}}{{e}^{2}} = 0.3598 e - 35 ,$$

showing the gravitational interaction to be even weaker than the already weak electromagnetic by about a Planck order of magnitude.

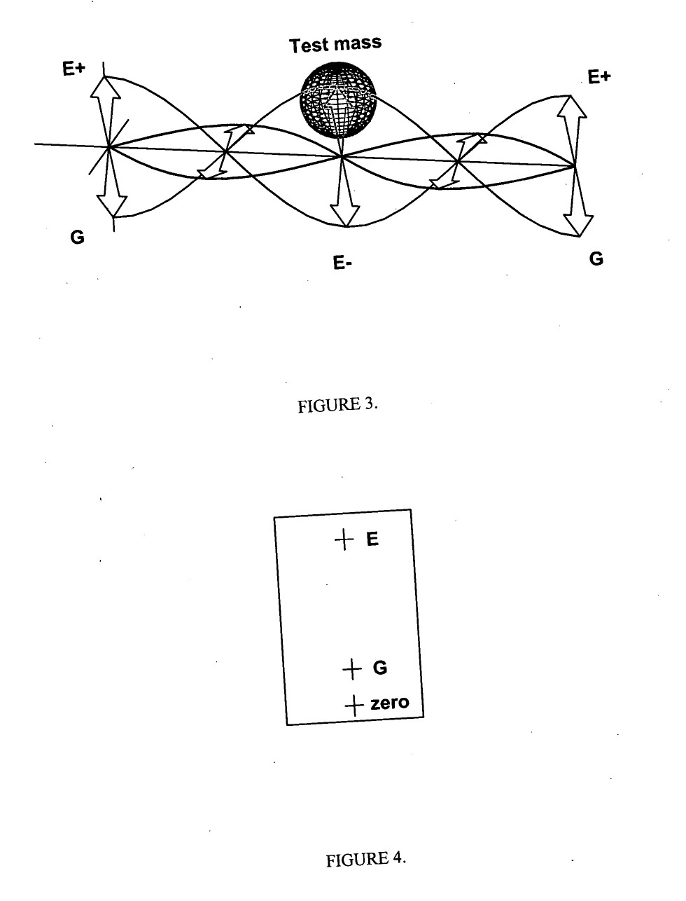

The present invention, in its primary form, is designed to detect the attractive interaction of the gravitational field component of a standing transverse gravitoelectromagnetic wave aligned with a test mass as shown in FIG. 3, wherein due to the reflective properties involved in setting up the standing wave the electric and magnetic, and their opposing gravitational components, are phase shifted from one another by π/2. Due to the formerly noted extremely low gravitational to electric to strength ratio, the instrument requires extreme measures in shielding out mechanical, temperature, and radiation effects, and therefore optimally performs its gravitational field component detection in deep space.

FIG. 3. A gravitational field component G, opposed to the E-electric component, of a standing transverse gravitoelectromagnetic wave aligned with a test mass.

A target incorporated in the present invention, shown in FIG. 4, indicates the deflection of the wave, calibrated to zero when there is no interaction. The wave is deflected to the G target when the gravitational component of the wave and the test mass are aligned, and deflected to the E target when the electric component of the wave and an attractive charge to the test mass are aligned.

FIG. 4. Target showing zero calibration for no deflection of the gravitoelectromagnetic wave, deflection to the G target when gravitational field components aligned, and deflection to the E target when attractive electric field components aligned.

The present invention in an alternate form also measures the acceleration of the test mass due to the attractive interaction of the gravitational component of the standing wave with the test mass. The invention also uses a traveling transverse gravitoelectromagnetic wave in the configuration just described.

Another variation of the present invention aligns the gravitational field components of two perpendicularly intersecting standing gravitoelectromagnetic waves, and measures the deflection of the waves due to their attractive gravitational field interaction. The result is the same as shown in FIG. 4, wherein the deflection is less when the gravitational components are aligned, than when the electric components are aligned. The invention also measures the deflection of such intersecting traveling gravitoelectromagnetic waves.

The means of interaction or communication between the electric, magnetic, and gravitational fields of energy wave-particles and those of matter particle-waves arises in the present embodiment through their common nature, the analysis of which begins with the transverse flux expansion-restoring force leading to EQ. (3) having associated with it a restoring acceleration, except the expansion-restoring force is acting along the two axes of the plane. In the present embodiment then, where the acceleration of flux expansion and contraction is indicating a force at work, since the symmetric velocity of the transverse linear flux displacement as it passes through a node would be c, what is indicated is a restoring acceleration with the dimensions and magnitude of c², thereby yielding the third factor in the matter-energy equivalency reported by A. Einstein (On the Electrodynamics of Moving Bodies, Annalen der Physik, 1905).

Next, wherein J. Maxwell (Matter and Motion, Dover, 1877) reports that the theory of potential energy is more complicated than that of kinetic energy, the present complication begins at a node of S, where in the presence of a nucleus the force of the traveling transverse planar flux expansion goes from a linear expansion along the axes of the traveling flux plane, to emerging from the node conserving charge and momentum as two completely coupled spherical expansions of the E⁻ to e⁻ field for the electron and E⁺ to e⁺ for the positron, with concurrent expansions for their respective B and G components. F. Crawford reports further, for a linearly polarized wave traveling in the +y direction with Bₓ=E_{z} for every y,t and with Eₒ in statvolt/cm

$$Energy flux = {S}_{y} = \frac{c}{4 π} {E}_{z} {B}_{x} = \frac{c}{4 π} {E}_{o}^{2} {cos}^{2} ( ω t - ky ) . \qquad ( 4 )$$

The time-averaged energy flux is obtained by replacing cos²(ωt−ky) with its average value of ½. In the prior art, it has been reasoned in the creation of one electron and one positron by a photon of electromagnetic energy, that if the pair were created from the photon it would be necessary to put m₋=−m₊ in the following equation, so that if the kinetic energies were zero this process would require only infinitesimal energy to initiate it,
hf=m₋c²+m₊c²+K₋+K₊. (5)

However in the present embodiment wherein the conservation of energy is seen to involve the conservation of field configuration energy, the gravitoelectromagnetic flux apportions according to

$$hf ⇒ \frac{c}{8 π} {E}_{o}^{2} = \frac{c}{8 π} ( {E}_{{m}_{-} {c}^{2}}^{2} + {E}_{{m}_{+} {c}^{2}}^{2} + {E}_{{K}_{-}}^{2} + {E}_{{K}_{+}}^{2} ) . \qquad ( 6 )$$

E. Purcell (Electricity and Magnetism, Berkeley Physics Course, Vol. II, McGraw-Hill, 1963) reports the energy associated with an electric field is equivalent to the work done in creating the field, according to the volume element

$$dW = \frac{c}{8 π} {E}_{{m}_{\pm } {c}^{2}}^{2} dV . \qquad ( 7 )$$

Therefore, after the expansion into the spherical rest mass configuration of the electron and positron's electric, magnetic, and gravitational fields, since they are all really one flux, the rest mass potential energy U is then simply the work done by the transverse linear expansion force acting into the spherical volume of all the space into which the fields extend

$$U = \frac{\frac{c}{8 π} ( {\int }_{{V}_{{E}^{-} , B , G}}^{{V}^{{e}^{-} , μ , g}} {E}_{{m}_{-} {c}^{2}}^{2} ⅆ V + {\int }_{{V}_{{E}^{+} , B , G}}^{{V}^{{e}^{+} , μ , g}} {E}_{{m}_{+} {c}^{2}}^{2} ⅆ V ) {\int }_{c}^{0} {ⅈ}^{2} ⅆ γ}{{c}^{2}} = \frac{1}{8 π} ( {\int }_{{V}_{{E}^{-} , B , G}}^{{V}^{{e}^{-} , μ , g}} {E}_{{m}_{-} {c}^{2}}^{2} ⅆ V + {\int }_{{V}_{{E}^{+} , B , G}}^{{V}^{{e}^{+} , μ , g}} {E}_{{m}_{+} {c}^{2}}^{2} ⅆ V ) = {m}_{-} + {m}_{+} . \qquad ( 8 )$$

It is of the essence of the present embodiment then that in pair production the traveling transverse expansion-restoring force drives the dual spherical work integration, including the c component integrating factor of ∫_{c}⁰i²dγ, into the rest mass potential energy configurations, collectively equivalent to a division by c², wherein the long-range electric and gravitational fields expand from each linear component axis by sin (ψ/2) for all r, as θ goes from 0→2π and ψ 0→π. Similar to the analogy of a coiled spring, the weaker coupled, lower spring constant, greater length, gravitational flux are coiled up tighter in the traveling flux vector so the transverse flux expansion-restoring force still expands equally and oppositely to the stronger coupled, higher spring constant, and shorter electric and magnetic flux; and thereby, apart from any external field, when spherically integrating expand proportionally further, which suggests there is a finite range to the electromagnetic and gravitational fields, as opposed to the infinite fields of the prior art. The magnetic field simultaneously expands by r sin (ψ), which newly configured particle-wave flux of the electron and positron then accord themselves to all the experimentally observed quantum mechanical behaviors of the prior art, just as their pair producing photon did in its initial traveling wave-particle configuration. Now though in the present embodiment, in incorporating gravitational components they have all become gravitons, the carriers of quantum gravity, based on their common relativistic medium which sits much more comfortably with the Copenhagen interpretation, the basic assertion of which is what we observe is all we can know.

What I claim as my invention is:

1. An instrument which detects the gravitational field component of a symmetrically modified unified gravitoelectromagnetic energy flux vector,
$$S = \frac{c}{4 π} ( E ⨯ B + {G}_{E} ⨯ {G}_{B} ) ,$$
Wherein:
the gravitational field component of a traveling transverse gravitoelectromagnetic wave is aligned with a test mass, and the deflection of the wave is measured.

2. The gravitational field component detection instrument as set forth in claim 1, wherein a standing gravitoelectromagnetic wave is aligned, and the acceleration of the test mass is measured.

3. The gravitational field component detection instrument as set forth in claim 1, wherein the gravitational field components of two perpendicularly intersecting traveling transverse gravitoelectromagnetic waves are aligned.

4. The gravitational field component detection instrument as set forth in claim 3, wherein two standing gravitoelectromagnetic waves are aligned.
